(19) United States
(12) Patent Application Publication
(10) Pub. No.: US 2026/0231579 A1
(43) Pub. Date: Aug. 6, 2026

(54) DISPLAY DEVICE

(71) Applicant: AUO Corporation, Hsinchu City (TW)

(72) Inventors: Wen-Ting Wang, Hsinchu City (TW); Kent-Yi Lee, Hsinchu City (TW); Yi-Ting Yeh, Hsinchu City (TW); Chia-Kai Chen, Hsinchu City (TW)

(73) Assignee: AUO Corporation, Hsinchu City (TW)

(21) Appl. No.: 19/348,807

(22) Filed: Oct. 3, 2025

(30) Foreign Application Priority Data
Feb. 6, 2025 (TW) 114104431

(51) Int. Cl. H10H 29/49; H10H 29/01; H10K 59/12; H10K 59/131

(52) U.S. Cl. CPC H10H 29/49; H10H 29/012; H10K 59/1201; H10K 59/131

(57) ABSTRACT

A display device has an island region and a bridge region adjacent to the island region, and includes a pixel structure, an organic insulating structure, a first signal line and a second signal line. The pixel structure is disposed in the island region. The organic insulating structure is disposed in the bridge region. The first signal line is disposed in the bridge region and electrically connected to a first signal source. The second signal line is disposed in the bridge region and electrically connected to a second signal source. The first and second signal lines extend from a top surface of the organic insulating structure to two opposite side surfaces of the organic insulating structure respectively.

### CROSS-REFERENCE TO RELATED APPLICATION

This application claims the priority benefit of Taiwan patent application no. 114104431, filed on February 6, 2025. The entirety of the above- mentioned patent application is hereby incorporated by reference herein and made a part of this specification.

### BACKGROUND

### Technical Field

The present disclosure relates to an optoelectronic device and, in particular, to a display device.

### Related Art

With the continuous innovation of display devices, stretchable, flexible, and unrestricted form factor characteristics have gradually gained attention to meet users' demands for arbitrarily stretching or bending display devices. In order to maximize the stretchability and flexibility of display devices as much as possible, one current approach is to fabricate pixel units in an island-like form and adopt circuit structures with a bridge-like form to connect pixel units to each other.

Current bridge-like circuit structures of stretchable display devices adopt a configuration of multiple wiring layers with organic insulating layers coated therebetween. However, due to the limited width of the bridge-like circuit structures, the coating yield of organic insulating layers deteriorates as the number of layers increases. Furthermore, the width of the conductive wires must also decrease as the number of layers increases, resulting in increased impedance and higher risk of burnout. Additionally, different power signal lines overlapping each other may also cause signal level problems.

### SUMMARY

One embodiment of the present disclosure provides a display device having an island region and a bridge region adjacent to the island region, and including a pixel structure disposed in the island region and an organic insulating structure located in the bridge region. The display device further includes a first signal line and a second signal line located in the bridge region, wherein the first signal line is electrically connected to a first signal source, the second signal line is electrically connected to a second signal source, and the first signal line and the second signal line extend from a top surface of the organic insulating structure to two opposite side surfaces of the organic insulating structure respectively.

In one embodiment of the present disclosure, the first signal source and the second signal source have different voltages.

In one embodiment of the present disclosure, in a direction from the top surface of the organic insulating structure toward a bottom surface of the organic insulating structure, the first signal line does not overlap the second signal line.

In one embodiment of the present disclosure, the organic insulating structure includes stacked organic insulating layers, and individual widths of the organic insulating layers decrease from a bottom layer to a top layer among the organic insulating layers.

In one embodiment of the present disclosure, the two opposite side surfaces of the organic insulating structure are linear, arc-shaped, or step-shaped.

In one embodiment of the present disclosure, the first signal line and the second signal line are respectively electrically connected to conductive stacks disposed along the two opposite side surfaces of the organic insulating structure.

In one embodiment of the present disclosure, the display device further includes third signal lines, wherein the third signal lines are located in the organic insulating structure and are respectively electrically connected to signal sources.

In one embodiment of the present disclosure, one of the third signal lines is electrically connected to the first signal line, and another one of the third signal lines is electrically connected to the second signal line.

In one embodiment of the present disclosure, the one of the third signal lines is electrically connected to the first signal line through a first via, the another one of the third signal lines is electrically connected to the second signal line through a second via, and the first via and the second via are each independently located in the bridge region or the island region.

In one embodiment of the present disclosure, the one and the another one of the third signal lines further extend along the two opposite side surfaces of the organic insulating structure respectively, and the one of the third signal lines is sandwiched between the first signal line and one of the two opposite side surfaces of the organic insulating structure, the another one of the third signal lines is sandwiched between the second signal line and the other of the two opposite side surfaces of the organic insulating structure.

To make the above features and advantages of the present disclosure more apparent and understandable, the following specific embodiments are provided and described in detail in conjunction with the accompanying drawings.

### BRIEF DESCRIPTION OF THE DRAWINGS

FIG. 1A is a schematically partial top view of a display device according to an embodiment of the present disclosure.

FIG. 1B is a schematic circuit diagram of an embodiment of a pixel structure of the display device of FIG. 1A.

FIG. 1C is a schematically cross-sectional view taken along a cross-sectional line A-A' of FIG. 1A.

FIG. 1D is a schematically cross-sectional view taken along a cross-sectional line B-B' of FIG. 1A.

FIG. 2 is a schematically partial cross-sectional view of a bridge region of a display device according to an embodiment of the present disclosure.

FIG. 3A is a schematically partial cross-sectional view of a bridge region of a display device according to an embodiment of the present disclosure.

FIG. 3B is a schematically partial cross-sectional view of an island region of the display device according to an embodiment of the present disclosure.

FIG. 4 is a schematically partial cross-sectional view of a bridge region of a display device according to an embodiment of the present disclosure.

FIG. 5 is a schematically partial cross-sectional view of a bridge region of a display device according to an embodiment of the present disclosure.

FIG. 6 is a schematically partial cross-sectional view of a bridge region of a display device according to an embodiment of the present disclosure.

FIG. 7 is a schematically partial cross-sectional view of a bridge region of a display device according to an embodiment of the present disclosure.

FIG. 8 is a schematically partial cross-sectional view of a bridge region of a display device according to an embodiment of the present disclosure.

FIG. 9A to FIG. 9E are schematically partial cross-sectional views of steps of a manufacturing method of a display device according to an embodiment of the present disclosure.

### DESCRIPTION OF THE EMBODIMENTS

Considering the particular amount of measurement and measurement-related errors discussed (i.e., the limitations of the measurement system), the terms “about,” “approximately,” or “substantially” used herein includes the average of the stated value and an acceptable range of deviations from the particular value as determined by those skilled in the art. For instance, the term “about” may refer to as being within one or more standard deviations of the stated value, or within ±30%, ±20%, ±10%, or ±5%. Furthermore, the terms “about,” “approximately,” or “substantially” as used herein may be chosen from a range of acceptable deviations or standard deviations depending on the properties, such as optical properties, etching properties, etc., rather than one standard deviation for all properties.

Furthermore, relative terms such as “below” or “bottom” and “above” or “top” may be used herein to describe a relationship of one element to another element as illustrated in the figures. It should be understood that relative terms are intended to encompass different orientations of the device in addition to the orientation depicted in the figures. For example, if the device in one of the figures is turned over, elements described as being on the “below” side of other elements would then be oriented on the “above” side of the other elements. Thus, the exemplary term “below” may include both “below” and “above” orientations, depending on the particular orientation of the figure. Similarly, if the device in one of the figures is turned over, elements described as “below” or “beneath” other elements would then be oriented “above” the other elements. Thus, the exemplary terms “below” or “beneath” may include both above and below orientations.

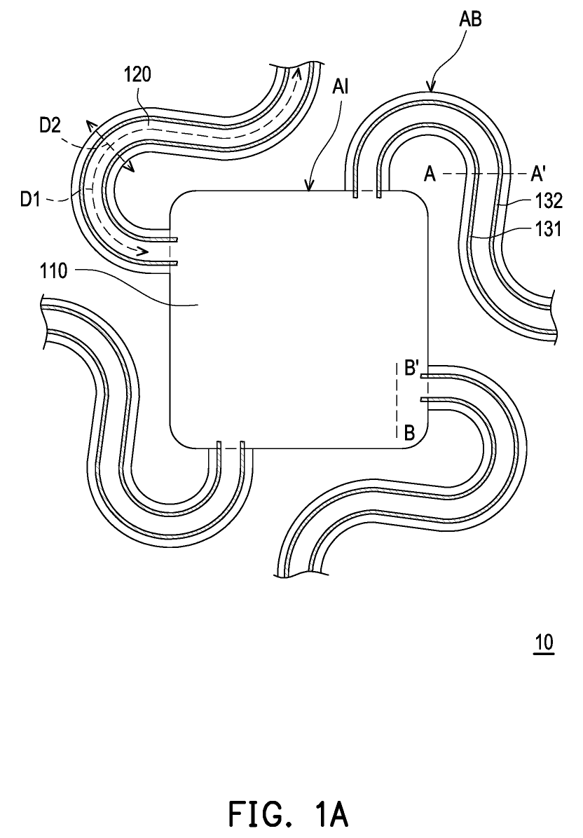

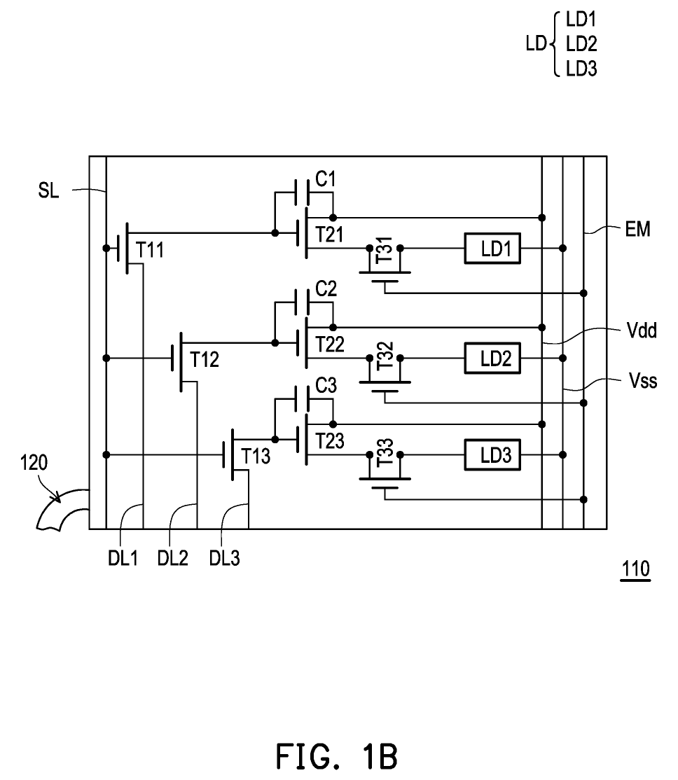

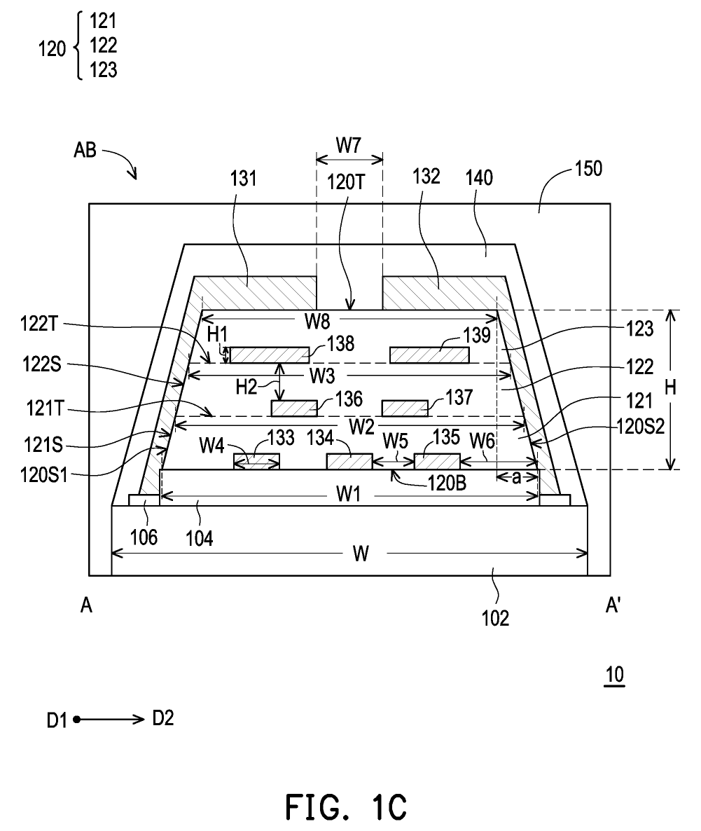

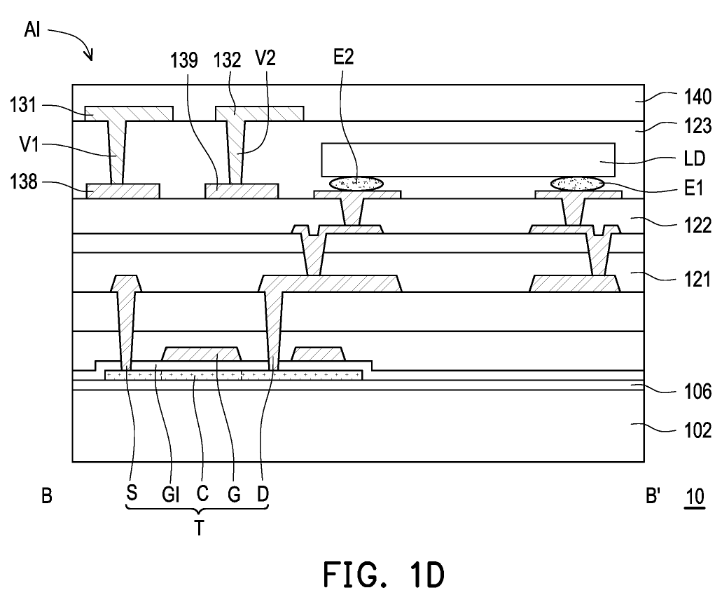

FIG. 1A is a schematically partial top view of a display device 10 according to an embodiment of the present disclosure. FIG. 1B is a schematic circuit diagram of an embodiment of a pixel structure 110 of the display device 10 of FIG. 1A. FIG. 1C is a schematically cross-sectional view taken along a cross-sectional line A-A' of FIG. 1A. FIG. 1D is a schematically cross-sectional view taken along a cross-sectional line B-B' of FIG. 1A. Next, with reference to FIG. 1A to FIG. 1D, the implementation of each element and film layer of the display device 10 will be described hereinafter, but the present disclosure is not limited thereto.

With reference to FIG. 1A, the display device 10 may have an island region AI and a bridge region AB, wherein the bridge region AB may be adjacent to the island region AI. In some embodiments, the island region AI may have a rectangular profile, but is not limited thereto. In other embodiments, the island region AI may have various geometric profiles as needed, for example, circular, polygonal, or irregular shapes. In some embodiments, the bridge region AB has a U-shaped profile, but is not limited thereto. In other embodiments, the bridge region AB may have various geometric profiles as needed, for example, S-shaped, V-shaped, or irregular profiles.

The display device 10 further includes a pixel structure 110 and an organic insulating structure 120, wherein the pixel structure 110 may be disposed in the island region AI, and the organic insulating structure 120 may be disposed in the bridge region AB. In some embodiments, the island region AI may refer to the region where the pixel structure 110 is located, and the bridge region AB may refer to the region where the organic insulating structure 120 is located.

In some embodiments, the display device 10 has multiple island regions AI and multiple bridge regions AB. The multiple bridge regions AB may be respectively located between two island regions AI, and may respectively connect corresponding two island regions AI. In some embodiments, one island region AI may connect multiple island regions AI through corresponding multiple bridge regions AB respectively. In some embodiments, the display device 10 includes multiple pixel structures 110 and multiple organic insulating structures 120, the multiple pixel structures 110 are respectively disposed in multiple island regions AI, the multiple organic insulating structures 120 are respectively disposed in multiple bridge regions AB and each extends between two pixel structures 110. In some embodiments, the multiple island regions AI of the display device 10 are arranged in an array, and the multiple pixel structures 110 of the display device 10 are respectively disposed in the multiple island regions AI and correspondingly arranged in an array. For example, the multiple island regions AI may be arranged edge-to-edge.

With reference to FIG. 1B, each pixel structure 110 may constitute one pixel or sub-pixel of the display device 10, for example. In some embodiments, the pixel structure 110 includes a light emitting element LD. The light emitting element LD may be, for example, a micro light emitting diode, an organic light emitting diode or other self-luminous components. For example, each pixel structure 110 includes three light emitting elements LD1, LD2, LD3, and the three light emitting elements LD1, LD2, LD3 may respectively have different light colors. For example, the light emitting element LD1 may emit red light, the light emitting element LD2 may emit green light, and the light emitting element LD3 may emit blue light, so that each pixel structure 110 may constitute one pixel of the display device 10, thereby achieving full-color display effects. However, the number or light color of the light emitting elements LD is not particularly limited. In some embodiments, each pixel structure 110 may include one, two, four, or more light emitting elements LD.

For example, the pixel structure 110 may further include transistors T11, T12, T13, transistors T21, T22, T23, transistors T31, T32, T33, and capacitors C1, C2, C3 configured with respect to the light emitting elements LD1, LD2, LD3 respectively. The gate electrodes of the transistor T11, the transistor T12 and the transistor T13 may be electrically connected to corresponding signal sources via signal lines SL (for example, serving as the scan lines) respectively, to receive corresponding gate signals via the signal lines SL respectively. The source electrodes of the transistors T11, T12, T13 may be electrically connected to corresponding signal sources via the signal line DL1, the signal line DL2 and the signal line DL3 (for example, serving as the data lines) respectively, to receive corresponding source signals via the signal lines DL1, DL2, DL3 respectively. The drain electrodes of the transistors T11, T12, T13 may be electrically connected to the gate electrodes of the transistor T21, the transistor T22 and the transistor T23 respectively to control the on or off of the transistors T21, T22, T23. The source electrodes of the transistors T21, T22, T23 and the cathodes of the light emitting elements LD1, LD2, LD3 may be electrically connected to corresponding signal source Vdd and signal source Vss respectively to receive corresponding voltage signals respectively. The drain electrodes of the transistors T21, T22, T23 may be electrically connected to the source electrodes of the transistor T31, the transistor T32 and the transistor T33 respectively, the gate electrodes of the transistors T31, T32, T33 may be electrically connected to a signal source EM, the drain electrodes of the transistors T31, T32, T33 may be electrically connected to the anodes of the light emitting elements LD1, LD2, LD3 respectively, and the transistors T31, T32, T33 may serve as switching components to control the light emitting time of the light emitting elements LD1, LD2, LD3 respectively. Additionally, both ends of the capacitor C1, the capacitor C2 and the capacitor C3 may be electrically connected to the drain electrodes of the transistors T11, T12, T13 and the source electrodes of the transistors T21, T22, T23 respectively, and the transistors T11, T12, T13 may control the charging time of the capacitors C1, C2, C3 respectively. The transistors T11, T12, T13 and the transistors T21, T22, T23 may provide stable current for the light emitting elements LD1, LD2, LD3 respectively within one frame time. Furthermore, the capacitors C1, C2, C3 may maintain the gate voltages of the transistors T21, T22, T23 after the scan pulse signals of the transistors T11, T12, T13 terminate, thereby providing continuous driving current for the light emitting elements LD1, LD2, LD3 until one frame time ends.

With reference to FIG. 1C, in some embodiments, the display device 10 may include a substrate 102. However, in certain embodiments, the display device 10 may not include the substrate 102. The substrate 102 may be used to carry the pixel structure 110 and the organic insulating structure 120. The substrate 102 may be a flexible substrate. The material of the substrate 102 may be, for example, polyimide (PI), polycarbonate (PC), polyester (PE), cyclic olefin copolymer (COC), metallocene-based cyclic olefin copolymer (mCOC) or other suitable materials, but is not limited thereto. In some embodiments, the width W of the substrate 102 ranges from 25 μm to 40 μm, but is not limited thereto.

With reference to FIG. 1A and FIG. 1C, the organic insulating structure 120 may be disposed above the substrate 102 within the bridge region AB. In some embodiments, the display device 10 may further include an insulating layer 104, and the insulating layer 104 may be located between the organic insulating structure 120 and the substrate 102. In some embodiments, the material of the insulating layer 104 is the same as the material of the organic insulating structure 120, but is not limited thereto. The organic insulating structure 120 and the insulating layer 104 may have a single-layer structure or a multi-layer structure. When the organic insulating structure 120 or the insulating layer 104 has a multi-layer structure, the layers of the multi-layer structure may include materials that are the same as each other or different from each other. For example, the material of the organic insulating structure 120 or the insulating layer 104 includes any one of acrylic, siloxane, polyimide, and epoxy, or a combination thereof, but is not limited thereto. In some embodiments, the organic insulating structure 120 and/or the insulating layer 104 may include an organic photoresist material.

The display device 10 further includes a signal line 131 and a signal line 132 located in the bridge region AB, and the signal line 131 and the signal line 132 are each electrically independent. In other words, the signal line 131 and the signal line 132 may be physically separated from each other and transmit different signals.

From the cross-sectional view of the organic insulating structure 120 as shown in FIG. 1C, the signal line 131 and the signal line 132 extend from a top surface of the organic insulating structure 120 to two opposite side surfaces of the organic insulating structure 120 respectively. For example, the signal line 131 extends from the top surface 120T of the organic insulating structure 120 to the side surface 120S1 of the organic insulating structure 120, and the signal line 132 extends from the top surface 120T of the organic insulating structure 120 to the side surface 120S2 of the organic insulating structure 120. By enabling the signal lines 131, 132 to respectively extend to the two opposite side surfaces of the organic insulating structure 120, the distribution area of the signal lines 131, 132 can be enlarged, thereby reducing the impedance of the signal lines 131, 132. Moreover, the signal line 131 and the signal line 132 do not overlap with each other, which can also avoid signal level problems. In some embodiments, the impedance of the signal lines 131, 132 can be reduced to as low as 0.5 times. In detail, compared to the design where the signal lines 131, 132 do not extend to the two opposite side surfaces of the organic insulating structure 120, the impedance of the signal lines 131, 132, which have been extended to the two opposite side surfaces of the organic insulating structure 120, can be reduced by up to 50%. Additionally, the signal lines 131, 132 encapsulating the side surfaces of the organic insulating structure 120 can also enhance the anti-strain capability of the organic insulating structure 120. In some embodiments, the organic insulating structure 120 can withstand at least 20% strain.

The side surface 120S1 may be opposite to the side surface 120S2. For example, with reference to both FIG. 1A and FIG. 1C simultaneously, at any sites in the bridge region AB, in a direction D2 substantially perpendicular to an extending direction D1 of the bridge region AB, the side surface 120S1 and the side surface 120S2 are respectively located on opposite sides of the bridge region AB. In some embodiments, the extending direction D1 of the bridge region AB may point to different orientations as the designated site changes, and the direction D2 may remain substantially perpendicular to the extending direction D1 as the designated site changes.

In some embodiments, the display device 10 may further include a buffer layer 106. However, in certain embodiments, the display device 10 may not include the buffer layer 106. The buffer layer 106 may be located between the signal lines 131, 132 and the substrate 102 to improve the adhesion of the signal lines 131, 132. In some embodiments, in the direction D2 substantially perpendicular to the extending direction D1 of the bridge region AB, the buffer layer 106 is located on opposite sides of the insulating layer 104, which can help improve the adhesion between the insulating layer 104 and the substrate 102. In some embodiments, the signal line 131 together with the buffer layer 106 and the signal line 132 together with the buffer layer 106 encapsulate the two opposite sidewalls of the insulating layer 104 in the direction D2 respectively. The material of the buffer layer 106 may include, for example, inorganic insulating materials such as silicon nitride (SiNx), silicon oxide (SiOx), silicon oxynitride (SiNxOy), titanium oxide (TiO), etc., but is not limited thereto.

In some embodiments, the display device 10 further includes a covering layer 140, and the covering layer 140 may cover the organic insulating structure 120, the signal lines 131, 132, and the buffer layer 106 on the substrate 102. For example, the covering layer 140 covers the portion of the top surface 120T of the organic insulating structure 120 that is not covered by the signal lines 131, 132, the top surfaces and side surfaces of the signal lines 131, 132, and the outer surface of the buffer layer 106, and the covering layer 140 physically contacts the top surface of the substrate 102. The material of the covering layer 140 is, for example, an organic photoresist material, but is not limited thereto.

In some embodiments, the display device 10 further includes a protective film 150, and the protective film 150 may be an ultra-thin stretchable film. The protective film 150 may encapsulate the top surface and side surfaces of the covering layer 140. In some embodiments, the protective film 150 further encapsulates the side surfaces of the substrate 102. The material of the protective film 150 is, for example, a transparent optical adhesive or a transparent encapsulation adhesive, but is not limited thereto.

The display device 10 may further include signal lines 133~139 located in the organic insulating structure 120. In some embodiments, the signal lines 131~139 extend from the bridge region AB to the island region AI and are electrically connected to multiple components of the pixel structure 110 respectively. For example, any one of the signal lines 131~139 may be electrically connected to any one of the signal lines SL, DL1, DL2, DL3 and signal sources Vdd, Vss, EM of the pixel structure 110 as shown in FIG. 1B.

The signal lines 131~139 may have an elongated shape, and the signal lines 131~139 may extend along the extending direction D1 of the bridge region AB. The signal lines 131~139 may have good conductivity and ductility or stretchability. Specifically, the material of the signal lines 131~139 may have a relatively small resistivity. For example, the resistivity of the signal lines 131~139 may range from 1.5x10⁻⁵ to 5x10⁻⁴ Ω*mm. For instance, the signal lines 131~139 may include a metal material, such as titanium, aluminum, copper, silver, etc., or an alloy thereof, but are not limited thereto. In some embodiments, the signal lines 131~139 further include a conductive oxide (for example, indium tin oxide, zinc aluminum oxide, zinc gallium oxide, zinc indium oxide, etc.), a conductive polymer (for example, poly(3,4-ethylenedioxythiophene):poly(styrenesulfonate) (PEDOT:PSS)), metal nanowires (for example, silver nanowires) or combinations thereof. In some embodiments, the signal lines 131~139 may independently have a single-layer structure or a multi-layer structure. When the signal lines 131~139 have a multi-layer structure, the layers in the multi-layer structure may include materials that are the same as each other or different from each other.

In some embodiments, the organic insulating structure 120 includes multiple organic insulating layers that are stacked, and the width of the multiple organic insulating layers decreases from the bottom layer to the top layer, so as to ensure smooth coverage of the upper organic insulating layers, thereby enhancing the coating yield of the organic insulating layers. The height H of the organic insulating structure 120 may range from approximately 7.5μm to 18μm, to ensure that the organic insulating structure 120 can be well formed, and sufficient signal lines can be provided within the organic insulating structure 120.

The organic insulating structure 120 may include three, four or an appropriate number of organic insulating layers. For example, the organic insulating structure 120 includes organic insulating layers 121, 122, and 123, where the organic insulating layer 121 may be the bottom layer closest to the substrate 102, the organic insulating layer 123 may be the top layer farthest from the substrate 102, and the organic insulating layer 122 may be located between the organic insulating layer 121 and the organic insulating layer 123. In some embodiments, the organic insulating layer 121 has a width W1, the organic insulating layer 122 has a width W2, the organic insulating layer 123 has a width W3, and W3<W2<W1.

In some embodiments, the organic insulating layer 122 covers only a top surface 121T of the organic insulating layer 121, but doesn’t cover a side surface 121S of the organic insulating layer 121. In some embodiments, the organic insulating layer 123 covers only a top surface 122T of the organic insulating layer 122, but doesn’t cover a side surface 122S of the organic insulating layer 122.

The cross-section of the organic insulating structure 120 may be substantially trapezoidal, to help improve the coating yield of the organic insulating layers (for example, the organic insulating layers 122, 123) of the organic insulating structure 120. In some embodiments, the side surfaces 120S1, 120S2 of the organic insulating structure 120 may have a substantially linear profile. In some embodiments, a width W8 of the top surface 120T of the organic insulating structure 120 is approximately 13μm to 21μm, for example 18μm, but is not limited thereto. In some embodiments, the organic insulating structure 120 has a spacing a between the orthographic projection of the top surface 120T of the organic insulating structure 120 on the bottom surface 120B of the organic insulating structure 120 and one end of the bottom surface 120B, and a height H of the organic insulating structure 120 may be approximately 3 times the spacing a. In other words, the spacing a may be approximately (1/3)H. In some embodiments, a width W1 of the bottom surface 120B of the organic insulating structure 120 is the sum of the width W8 of the top surface 120T and 2 spacings a (i. e., (2/3)H), that is, W1=W8+(2/3)H. In some embodiments, H=3a±1.5μm, but is not limited thereto.

The signal lines 133, 134, 135 may be located in the organic insulating layer 121, the signal lines 136, 137 may be located in the organic insulating layer 122, and the signal lines 138, 139 may be located in the organic insulating layer 123. In some embodiments, a minimum line width W4 of the signal lines 133~139 is approximately 2.5μm, to avoid the signal lines 133~139 having excessive resistance. In some embodiments, a thickness H1 of the signal lines 133~139 is approximately 5,000 angstroms (Å) to 10,000Å, to ensure the signal lines 133~139 do not have excessive resistance, while the signal lines 133~139 can be well encapsulated in the organic insulating structure 120.

The spacing between the signal lines located in the same organic insulating layer may be approximately 2.8μm to 4μm. For example, a spacing W5 between the signal lines 133, 134, 135 located in the same organic insulating layer 121 is approximately 2.8μm to 4μm. When the spacing W5 is less than 2.8μm, it may not be possible to ensure that the etching process used to pattern the signal lines 133, 134, 135 can form the signal lines 133, 134, 135 that are physically separated from each other. When the spacing W5 is greater than 4μm, it may not be possible to form a sufficient number of signal lines in the organic insulating structure 120 of limited width, or it may cause the signal lines to be exposed from the side surfaces of the organic insulating structure 120.

In some embodiments, a minimum distance W6 between the signal lines 133, 134, 135 and the side surfaces 120S1, 120S2 of the organic insulating structure 120 is approximately 1.5μm, to avoid the organic insulating structure 120 unable to properly encapsulate the signal lines 133, 135, or to avoid the signal line 133 or the signal line 135 being exposed from the side surface 120S1 or the side surface 120S2 of the organic insulating structure 120.

In some embodiments, the minimum spacing between the signal lines located in different organic insulating layers is approximately 2μm to 4.5μm. For example, there is a minimum spacing H2 between the signal line 136 located in the organic insulating layer 122 and the signal line 138 located in the organic insulating layer 123, and the minimum spacing H2 is approximately 2μm to 4.5μm. When the minimum spacing H2 is less than 2μm, the signal transmitted by the signal line 136 may interfere with the signal transmitted by the signal line 138. For example, coupling phenomenon may occur, causing signal level problems. When the minimum spacing H2 is greater than 4.5μm, the organic insulating layer 122 may be too thick to be well patterned.

In some embodiments, a spacing W7 between the signal line 131 and the signal line 132 is approximately 4μm to 12μm. Since the signal line 131 and the signal line 132 may transmit signals with larger currents, designing the spacing W7 between the signal line 131 and the signal line 132 to be larger than the spacing W5 between the signal lines located in the same organic insulating layer 121, 122 or 123 can prevent the level of signals transmitted by the signal lines 131, 132 from deviating, thereby improving the signal transmission efficiency of the signal lines 131, 132.

With reference to FIG. 1D, in some embodiments, the pixel structure 110 may also include the buffer layer 106, the organic insulating layers 121~123 and the covering layer 140. A transistor T of the pixel structure 110 may be disposed between the buffer layer 106 and the organic insulating layer 121, and and the light emitting element LD of the pixel structure 110 may be set between the organic insulating layer 122 and the organic insulating layer 123. The transistor T may include a gate electrode G, a source electrode S, a drain electrode D, a channel C and a gate insulating layer GI located between the gate electrode G and the channel C.

In some embodiments, the signal lines 131, 132, 138, 139 may individually extend to the pixel structure 110 in the island region AI, and in the island region AI, the signal lines 131, 132 may be electrically connected to the signal lines 138, 139 respectively through via holes V1, V2 that pass through the organic insulating layer 123.

With reference to FIG. 1B and FIG. 1D simultaneously, the signal lines 131, 138 may be electrically connected to the signal source Vdd and transmit a high voltage signal to the capacitors C1~C3 and the transistors T21~T23 of the pixel structure 110. Additionally, the signal lines 132, 139 may be electrically connected to the signal source Vss and transmit a voltage signal to an electrode E1 of the light emitting element LD. In some embodiments, the signal source Vdd and the signal source Vss have different voltages, but are not limited thereto. In some embodiments, the drain electrode D of the transistor T (for example, corresponding to the transistor T31, T32 or T33 in FIG. 1B) may be electrically connected to an electrode E2 of the light emitting element LD.

With reference to FIG. 1B and FIG. 1C simultaneously, in some embodiments, the signal lines 133~135 may be electrically connected to the signal lines DL1, DL2, DL3 respectively. In some embodiments, one of the signal lines 136~137 may be electrically connected to the signal line SL. With reference to FIG. 1B to FIG. 1D simultaneously, in some embodiments, the other one of the signal lines 136~137 may be electrically connected to the signal source EM and transmit a signal to the gate electrode G of the transistor T.

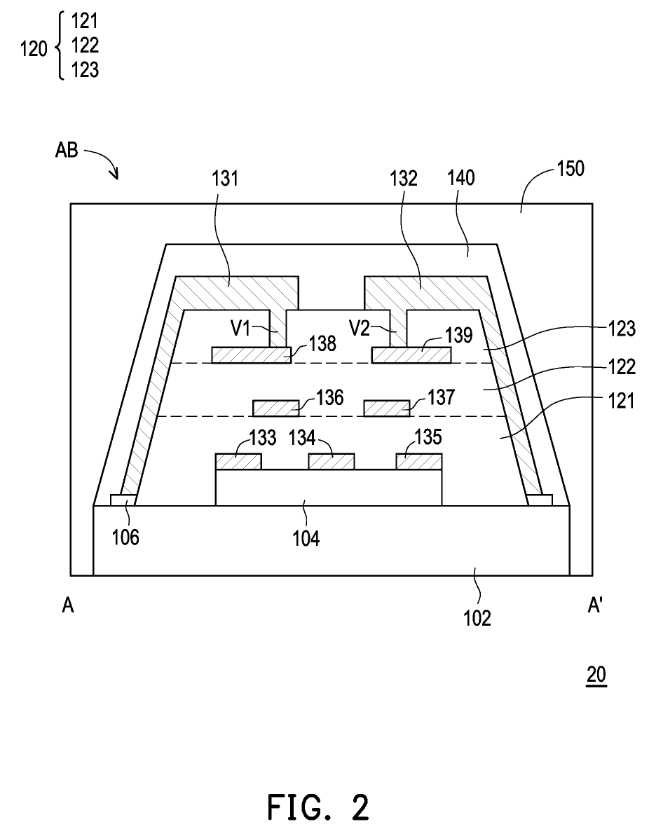

FIG. 2 is a schematically partial cross-sectional view of a bridge region AB of a display device 20 according to an embodiment of the present disclosure. In FIG. 2, the display device 20 may be considered as another implementation aspect of the display device 10 as shown in FIG. 1A to FIG. 1D, and the display device 20 may have all the components of the display device 10. This embodiment adopts the same or similar reference numerals and related content as the embodiments of FIG. 1A to FIG. 1D.

Compared with the display device 10 as shown in FIG. 1C, the main difference of the display device 20 as shown in FIG. 2 lies in that: the via holes V1, V2 passing through the organic insulating layer 123 of the display device 20 may be located in the bridge region AB, rather than the island region AI. That is, the signal line 131 may be electrically connected to the signal line 138 through the via hole V1 located in the bridge region AB, and the signal line 132 may be electrically connected to the signal line 139 through the via hole V2 located in the bridge region AB.

In some embodiments, one of the via holes V1, V2 is located in the bridge region AB, while the other of the via holes V1, V2 is located in the island region AI. For example, the via hole V1 is located in the bridge region AB, while the via hole V2 is located in the island region AI. Alternatively, the via hole V1 may be located in the island region AI, while the via hole V2 may be located in the jjjkorjetgpjieuji32k7 bridge region AB.

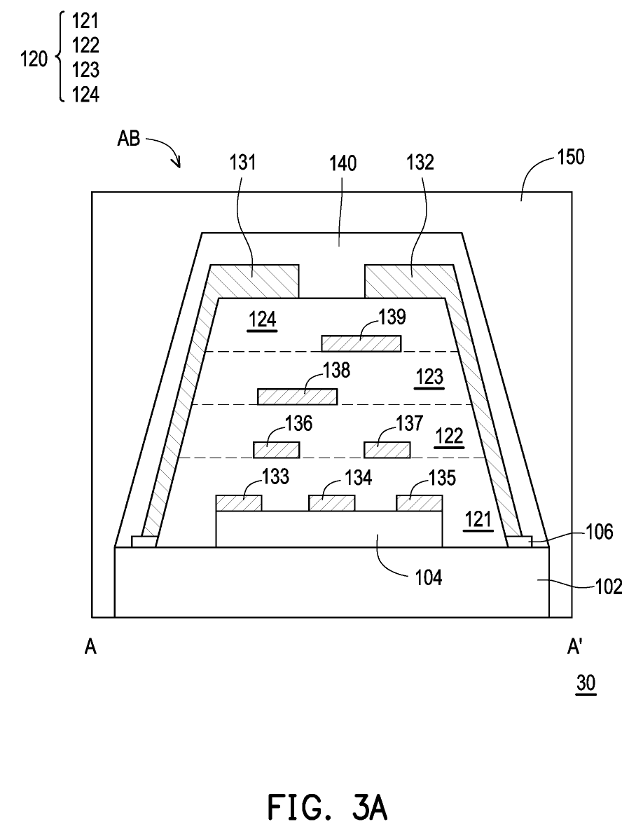

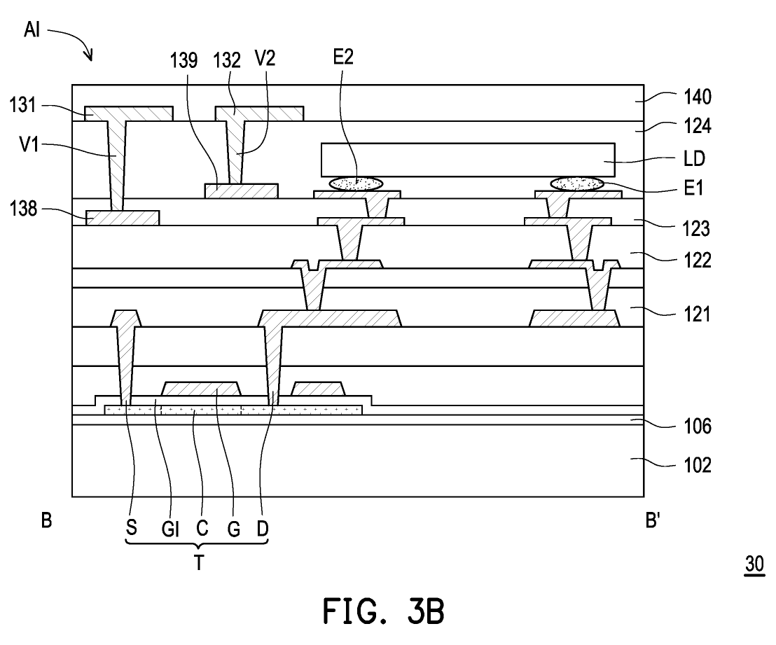

FIG. 3A is a schematically partial cross-sectional view of a bridge region AB of a display device 30 according to an embodiment of the present disclosure. FIG. 3B is a schematically partial cross-sectional view of an island region AI of the display device 30 according to an embodiment of the present disclosure. In FIG. 3A to FIG. 3B, the display device 30 may be considered as another implementation aspect of the display device 10 as shown in FIG. 1A to FIG. 1D, and the display device 30 may have all the components of the display device 10. This embodiment adopts the same or similar reference numerals and related content as the embodiments of FIG. 1A to FIG. 1D.

Compared with the display device 10 as shown in FIG. 1A to FIG. 1D, the main difference of the display device 30 as shown in FIG. 3A to FIG. 3B lies in that the organic insulating structure 120 of the display device 30 may include four organic insulating layers. For example, the organic insulating structure 120 includes organic insulating layers 121, 122, 123 and 124, wherein the organic insulating layer 121 may be the bottom layer closest to the substrate 102, the organic insulating layer 124 may be the top layer farthest from the substrate 102, the organic insulating layer 122 may be located between the organic insulating layer 121 and the organic insulating layer 124, and the organic insulating layer 123 may be located between the organic insulating layer 122 and the organic insulating layer 124. In some embodiments, the widths of the organic insulating layers 121~124 decrease progressively from the bottom layer to the top layer.

Additionally, the signal line 138 may be independently located in the organic insulating layer 123, and the signal line 139 may be independently located in the organic insulating layer 124, so that the signal lines 138, 139 may have wider widths to further reduce the impedance of the signal lines 138, 139.

In some embodiments, in the island region AI, the signal line 131 may be electrically connected to the signal line 138 via the via hole V1 passing through the organic insulating layers 123, 124, and the signal line 132 may be electrically connected to the signal line 139 via the via hole V2 passing through the organic insulating layer 124.

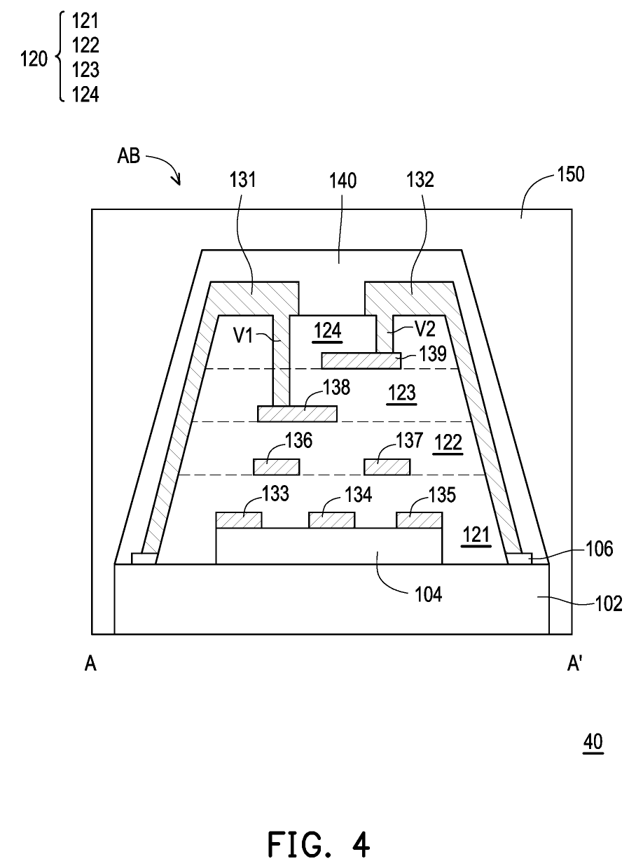

FIG. 4 is a schematically partial cross-sectional view of a bridge region AB of a display device 40 according to an embodiment of the present disclosure. In FIG. 4, the display device 40 may be considered as another implementation aspect of the display device 30 as shown in FIG. 3A to FIG. 3B, and the display device 40 may have all the components of the display device 30. This embodiment adopts the same or similar reference numerals and related content as the embodiments of FIG. 3A to FIG. 3B.

Compared with the display device 30 as shown in FIG. 3A, the main difference of the display device 40 shown in FIG. 4 lies in that the via holes V1, V2 in the organic insulating layers 123, 124 of the display device 40 may be located in the bridge region AB, rather than the island region AI. That is, the signal line 131 may be electrically connected to the signal line 138 via the via hole V1 located in the bridge region AB and passing through the organic insulating layers 123, 124, and the signal line 132 may be electrically connected to the signal line 139 via the via hole V2 located in the bridge region AB and passing through the organic insulating layer 124.

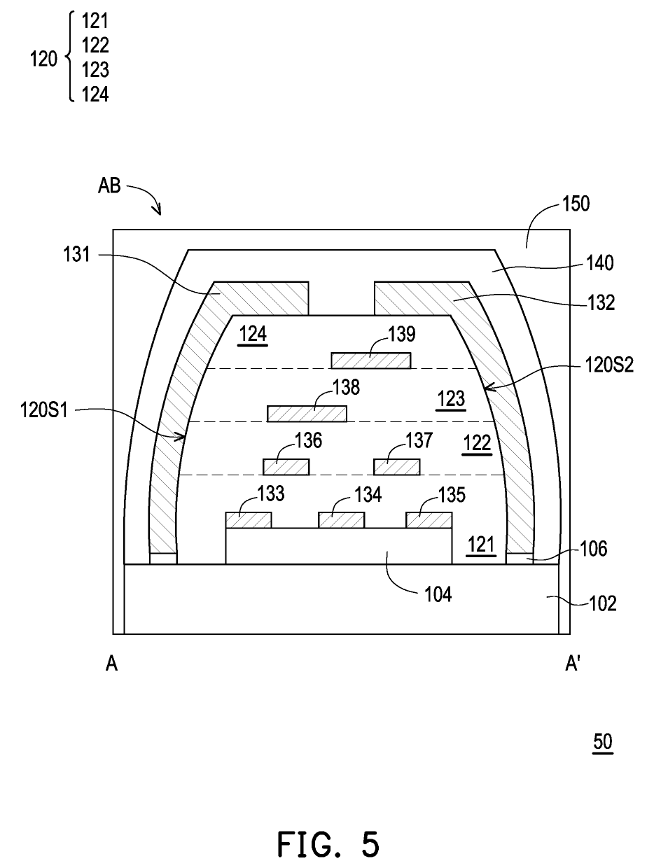

FIG. 5 is a schematically partial cross-sectional view of a bridge region AB of a display device 50 according to an embodiment of the present disclosure. In FIG. 5, the display device 50 may be considered as another implementation aspect of the display device 30 as shown in FIG. 3A to FIG. 3B, and the display device 50 may have all the components of the display device 30. This embodiment adopts the same or similar reference numerals and related content as the embodiments of FIG. 3A to FIG. 3B.

Compared with the display device 30 as shown in FIG. 3A, the main difference of the display device 50 as shown in FIG. 5 lies in that the side surfaces 120S1, 120S2 of the organic insulating structure 120 of the display device 50 may have an arc-shaped profile. In this way, the width of the organic insulating layers 121~124 of the organic insulating structure 120 may be increased, enabling the process for forming the signal lines 131~139 to have an increased process margin.

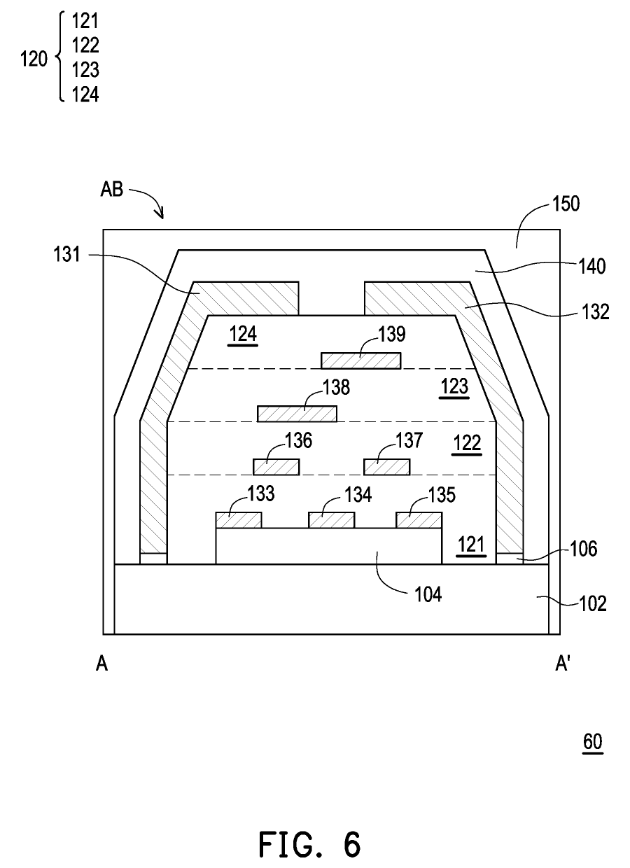

FIG. 6 is a schematically partial cross-sectional view of a bridge region AB of a display device 60 according to an embodiment of the present disclosure. In FIG. 6, the display device 60 may be considered as another implementation aspect of the display device 30 as shown in FIG. 3A to FIG. 3B, and the display device 60 may have all the components of the display device 30. This embodiment adopts the same or similar reference numerals and related content as the embodiments of FIG. 3A to FIG. 3B.

Compared with the display device 30 as shown in FIG. 3A, the main difference of the display device 60 as shown in FIG. 6 lies in that the organic insulating layers 121, 122 of the organic insulating structure 120 of the display device 60 have a rectangular profile, and the organic insulating layers 123, 124 have a trapezoidal profile. In this way, the coverage difficulty of the organic insulating layers 121~124 may be reduced, and the width of the organic insulating layers 121~124 may be further increased, enabling the process for forming the signal lines 131~139 to have an increased process margin.

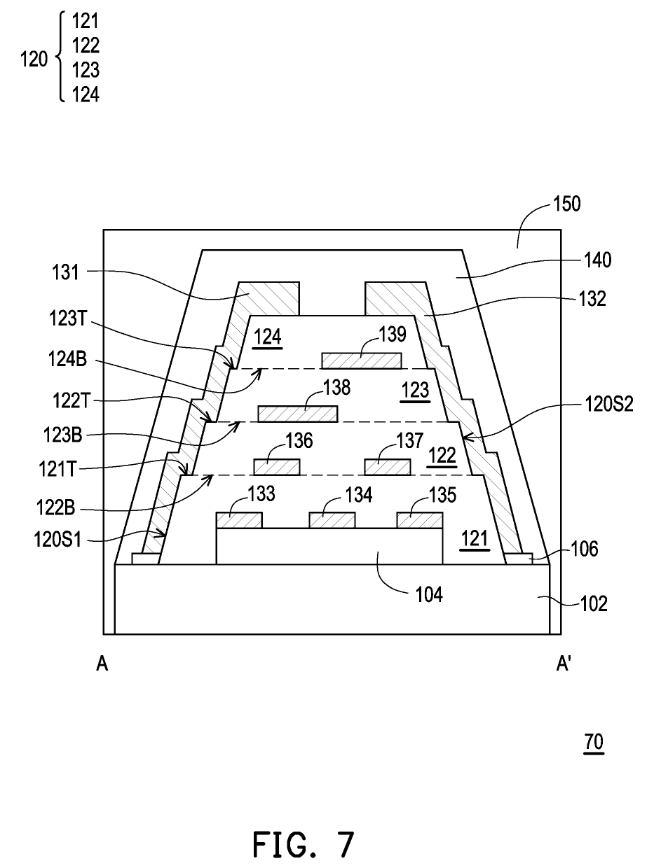

FIG. 7 is a schematically partial cross-sectional view of a bridge region AB of a display device 70 according to an embodiment of the present disclosure. In FIG. 7, the display device 70 may be considered as another implementation aspect of the display device 30 as shown in FIG. 3A to FIG. 3B, and the display device 70 may have all the components of the display device 30. This embodiment adopts the same or similar reference numerals and related content as the embodiments of FIG. 3A to FIG. 3B.

Compared with the display device 30 as shown in FIG. 3A, the main difference of the display device 70 as shown in FIG. 7 lies in that the side surfaces 120S1, 120S2 of the organic insulating structure 120 of the display device 70 may have a step-shaped profile. In other words, the width of the top surface 121T of the organic insulating layer 121 of the organic insulating structure 120 may be greater than the width of the bottom surface 122B of the organic insulating layer 122; the width of the top surface 122T of the organic insulating layer 122 may be greater than the width of the bottom surface 123B of the organic insulating layer 123; and the width of the top surface 123T of the organic insulating layer 123 may be greater than the width of the bottom surface 124B of the organic insulating layer 124. In this way, the coating yield of the organic insulating layers 122~124 may be enhanced, facilitating the achievement of the predetermined thickness of the signal lines 131, 132 on the side surfaces 120S1, 120S2 of the organic insulating structure 120. In some embodiments, portions of the signal lines 131, 132 on the side surfaces 120S1, 120S2 of the organic insulating structure 120 may respectively conform to the side surfaces 120S1, 120S2 of the organic insulating structure 120 and have a step-shaped profile.

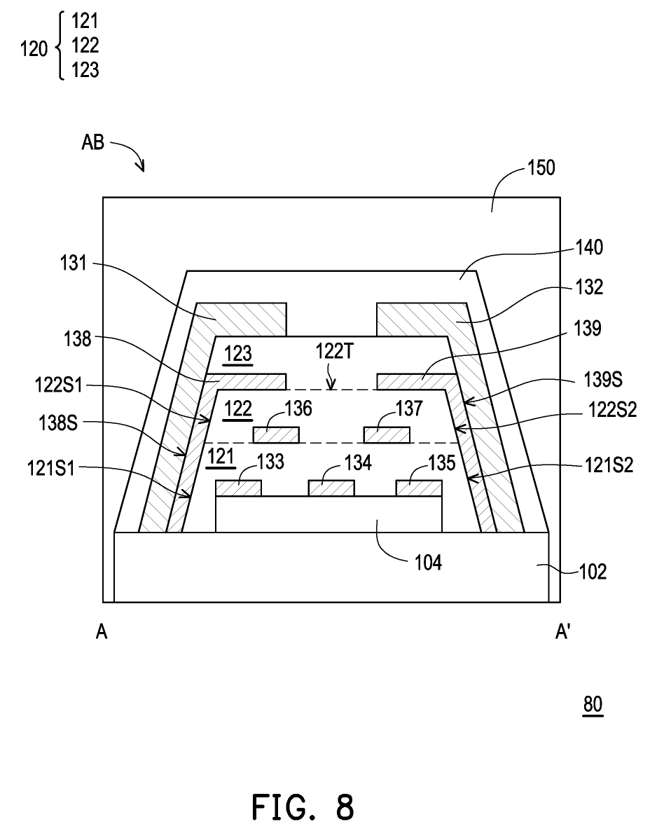

FIG. 8 is a schematically partial cross-sectional view of a bridge region AB of a display device 80 according to an embodiment of the present disclosure. In FIG. 8, the display device 80 may be considered as another implementation aspect of the display device 20 as shown in FIG. 2, and the display device 80 may have all the components of the display device 20. This embodiment adopts the same or similar reference numerals and related content as the embodiment of FIG. 2.

Compared with the display device 20 as shown in FIG. 2, the main difference of the display device 80 as shown in FIG. 8 lies in that the signal line 138 of the display device 80 may extend from the top surface 122T of the organic insulating layer 122 to the side surface 122S1 of the organic insulating layer 122, and the signal line 139 may extend from the top surface 122T of the organic insulating layer 122 to the side surface 122S2 of the organic insulating layer 122, wherein the side surface 122S1 and the side surface 122S2 of the organic insulating layer 122 are opposite to each other. The signal line 131 may physically contact the side surface 138S of the signal line 138 to electrically connect the signal line 138, and the signal line 132 may physically contact the side surface 139S of the signal line 139 to electrically connect the signal line 139. In this way, the signal lines 131, 132 respectively stacked the signal lines 138, 139 may increase the thickness, thereby improving signal quality, and may not require the aforementioned via holes V1, V2.

In some embodiments, the signal line 138 is located between the side surface 122S1 of the organic insulating layer 122 and the signal line 131. In some embodiments, the signal line 139 is located between the side surface 122S2 of the organic insulating layer 122 and the signal line 132. In some embodiments, the signal line 138 extends from the top surface 122T of the organic insulating layer 122 to the side surface 122S1 of the organic insulating layer 122 and the side surface 121S1 of the organic insulating layer 121. In some embodiments, the signal line 139 extends from the top surface 122T of the organic insulating layer 122 to the side surface 122S2 of the organic insulating layer 122 and the side surface 121S2 of the organic insulating layer 121, wherein the side surface 121S2 and the side surface 121S1 of the organic insulating layer 121 are opposite to each other.

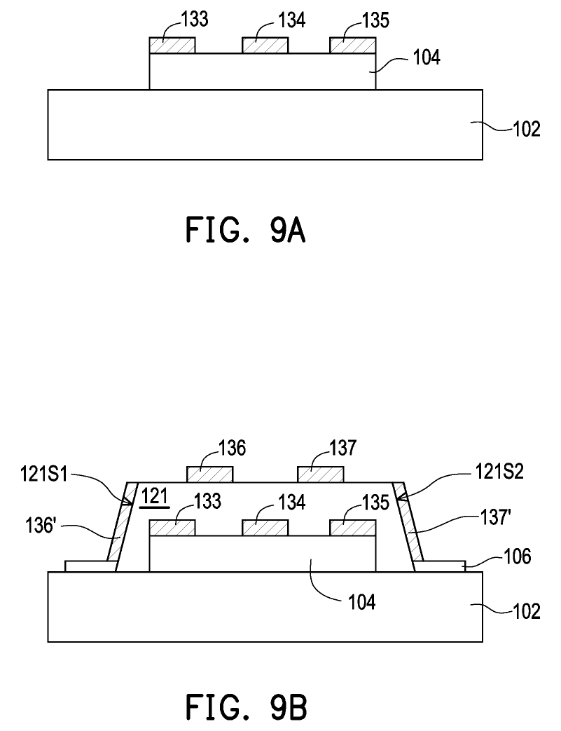

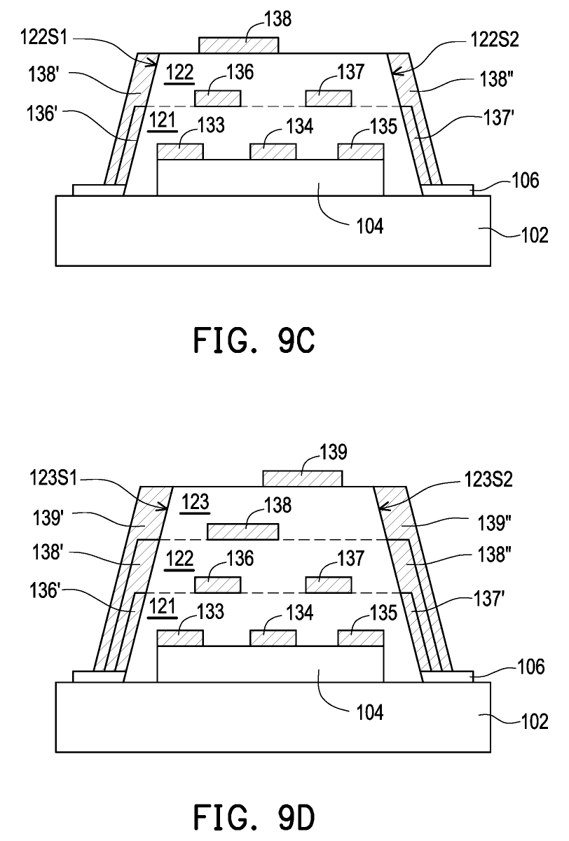

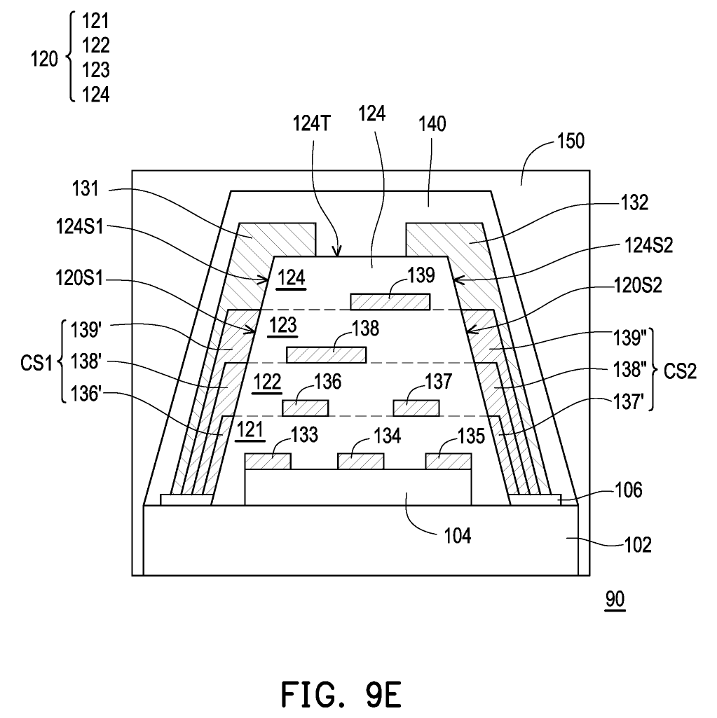

FIG. 9A to FIG. 9E are schematically partial cross-sectional views of steps of a manufacturing method of a display device 90 according to an embodiment of the present disclosure. Next, with reference to FIG. 9A to FIG. 9E, the implementation of the manufacturing method of the display device 90 will be described hereinafter, but the present disclosure is not limited thereto.

With reference to FIG. 9A, an insulating layer 104 is formed in a region predetermined to form a bridge region AB on the substrate 102. Forming the insulating layer 104 may adopt, for example, a spin coating process, a lithography process and an ashing process, but the present disclosure is not limited thereto. In some embodiments, the material used for forming the insulating layer 104 includes the organic photoresist material, but the present disclosure is not limited thereto.

Next, by adopting, for example, a thin film deposition process, the lithography process and an etching process, signal lines 133, 134, 135 are formed on the insulating layer 104. In some embodiments, the signal lines 133, 134, 135 are physically separated from each other. In some embodiments, the signal lines 133, 134, 135 extend substantially equidistantly from each other in the bridge region AB. The material used for forming the signal lines 133, 134, 135 may include a metal material, such as titanium, aluminum, copper, silver, etc., or a combination thereof, or other appropriate conductive materials or a combination thereof, or a combination of the aforementioned metal material with other appropriate conductive material. For example, the signal lines 133, 134, 135 may each include a titanium/aluminum/titanium stack.

Next, with reference to FIG. 9B, an organic insulating layer 121 is formed on the substrate 102, and the organic insulating layer 121 can cover the signal lines 133, 134, 135, the insulating layer 104 and the substrate 102. Forming the organic insulating layer 121 may adopt, for example, the spin coating process, the lithography process and the ashing process, but the present disclosure is not limited thereto. In some embodiments, the material used for forming the organic insulating layer 121 includes the organic photoresist material, but the present disclosure is not limited thereto. In some embodiments, the organic insulating layer 121 is formed in a region predetermined to form the bridge region AB and an island region AI on the substrate 102 (for example, with reference to FIG. 3B).

Next, a buffer layer 106 is formed on the substrate 102, and in the direction from the signal line 133 toward the signal line 135, the buffer layer 106 may be located on two opposite sides of the organic insulating layer 121. Forming the buffer layer 106 may adopt, for example, the thin film deposition process, the lithography process and the etching process, but the present disclosure is not limited thereto. In some embodiments, the material used for forming the buffer layer 106 includes an inorganic insulating material, such as SiNx, SiOx, SiNxOy, TiO, etc.

Next, by adopting for example the thin film deposition process, the lithography process and the etching process, signal lines 136, 137 are formed on the organic insulating layer 121. The signal line 136 and the signal line 137 may be physically separated from each other. In some embodiments, in the process of forming the signal lines 136, 137, conductive layers 136', 137' are also formed, wherein the conductive layer 136' may be located on a side surface 121S1 of the organic insulating layer 121, and the conductive layer 137' may be located on a side surface 121S2 of the organic insulating layer 121. In some embodiments, the conductive layers 136', 137' extend along the side surfaces 121S1, 121S2 of the organic insulating layer 121 respectively to the top surface of the buffer layer 106.

Next, with reference to FIG. 9C, by adopting for example the spin coating process, the lithography process and the ashing process, an organic insulating layer 122 is formed on the organic insulating layer 121 and the signal lines 136, 137, such that the organic insulating layer 122 encapsulates the signal lines 136, 137. In some embodiments, the material used for forming the organic insulating layer 122 includes the organic photoresist material, but the present disclosure is not limited thereto. In some embodiments, the organic insulating layer 122 is formed in the region predetermined to form the bridge region AB and the island region AI on the substrate 102 (for example, with reference to FIG. 3B).

Next, by adopting for example the thin film deposition process, the lithography process and the etching process, a signal line 138 is formed on the organic insulating layer 122. In some embodiments, in the process of forming the signal line 138, conductive layers 138', 138" are also formed, wherein the conductive layer 138' may be located on a side surface 122S1 of the organic insulating layer 122 and the conductive layer 136', and the conductive layer 138" may be located on a side surface 122S2 of the organic insulating layer 122 and the conductive layer 137'. In some embodiments, the conductive layers 138', 138" extend along the conductive layers 136', 137' respectively to the top surface of the buffer layer 106.

Next, with reference to FIG. 9D, by adopting for example the spin coating process, the lithography process and the ashing process, an organic insulating layer 123 is formed on the organic insulating layer 122 and the signal line 138, such that the organic insulating layer 123 encapsulates the signal line 138. In some embodiments, the material used for forming the organic insulating layer 123 includes the organic photoresist material, but the present disclosure is not limited thereto. In some embodiments, the organic insulating layer 123 is formed in the region predetermined to form the bridge region AB and the island region AI on substrate 102 (for example, with reference to FIG. 3B).

Next, by adopting for example the thin film deposition process, the lithography process and the etching process, a signal line 139 is formed on the organic insulating layer 123. In some embodiments, in the process of forming the signal line 139, conductive layers 139', 139" are also formed, wherein the conductive layer 139' may be located on a side surface 123S1 of the organic insulating layer 123 and the conductive layer 138', and the conductive layer 139" may be located on a side surface 123S2 of the organic insulating layer 123 and the conductive layer 138". In some embodiments, the conductive layers 139', 139" extend along the conductive layers 138', 138" respectively to the top surface of the buffer layer 106.

Next, with reference to FIG. 9E, by adopting for example the spin coating process, the lithography process and the ashing process, an organic insulating layer 124 is formed on the organic insulating layer 123 and the signal line 139, such that the organic insulating layer 124 encapsulates the signal line 139. In some embodiments, the material used for forming the organic insulating layer 124 includes the organic photoresist material, but the present disclosure is not limited thereto. In some embodiments, the organic insulating layer 124 is formed in the region predetermined to form the bridge region AB and the island region AI on the substrate 102 (for example, with reference to FIG. 3B).

Next, by adopting for example the thin film deposition process, the lithography process and the etching process, signal lines 131, 132 are formed on the organic insulating layer 124, the signal line 131 extends from a top surface 124T of the organic insulating layer 124 to a side surface 124S1 of the organic insulating layer 124, and the signal line 132 extends from the top surface 124T of the organic insulating layer 124 to a side surface 124S2 of the organic insulating layer 124. In some embodiments, signal line 131 also extends along the conductive layer 139' to the top surface of the buffer layer 106. In some embodiments, the signal line 132 also extends along the conductive layer 139" to the top surface of the buffer layer 106.

In some embodiments, the conductive layers 136', 138', 139' are sequentially stacked on the side surface 120S1 of the organic insulating structure 120 and are in physical contact with each other, thereby forming a conductive stack CS1 in physical contact with the signal line 131. In this way, it is possible to ensure that the conductive stack CS1 with sufficient thickness and electrically connected to the signal line 131 is formed on the side surface 120S1 of the organic insulating structure 120, such that the signal line 131 combined with the conductive stack CS1 has reduced impedance. Similarly, the conductive layers 137', 138", 139" may be sequentially stacked on the side surface 120S2 of the organic insulating structure 120 and are in physical contact with each other, so as to form a conductive stack CS2 in physical contact with the signal line 132, thereby ensuring that the conductive stack CS2 with sufficient thickness and electrically connected to the signal line 132 is formed on the side surface 120S2 of the organic insulating structure 120, such that the signal line 132 combined with the conductive stack CS2 has reduced impedance.

Next, by adopting for example the spin coating process, the lithography process and the ashing process, a cap layer 140 is formed on the organic insulating layer 124, the signal lines 131, 132 and the substrate 102, and the cap layer 140 may completely cover the organic insulating layer 124, the signal lines 131, 132 and the substrate 102. In some embodiments, the cap layer 140 is located in the region predetermined to form the bridge region AB and the island region AI on the substrate 102 (for example, referring to FIG. 3B).

Next, transparent optical adhesive or transparent encapsulation adhesive may be coated on a top surface and a side surface of the cap layer 140 by for example the spray coating process, so as to form a protective film 150. In some embodiments, the protective film 150 further encapsulates a side surface of the substrate 102.

In summary, the display device of the present disclosure enables the signal lines to extend to the side surfaces of the organic insulating structure, thereby enlarging the distribution area of the signal lines, thus reducing impedance of the signal lines. Moreover, since the signal lines do not overlap with each other, it can also avoid problems related to the signal level. Additionally, the signal lines encapsulating the side surfaces of the organic insulating structure can enhance the strain resistance capability of the organic insulating structure. Furthermore, by making the widths of the organic insulating layers of the organic insulating structure decrease progressively from the bottom layer to the top layer, or by making the side surface of the organic insulating structure have the step-shaped profile, the coating yield of the organic insulating layers of the organic insulating structure can be further increased.

Although the present disclosure has been disclosed above with reference to the embodiments, it is not intended to limit the present disclosure. Any person having ordinary knowledge in the technical field may make slight modifications and refinements without departing from the spirit and scope of the present disclosure. Therefore, the protection scope of the present disclosure shall be defined by the appended claims.

What is claimed is:

1. A display device, having an island region and a bridge region adjacent to the island region, and comprising:
a pixel structure disposed in the island region;
an organic insulating structure located in the bridge region;
a first signal line located in the bridge region and electrically connected to a first signal source; and
a second signal line located in the bridge region and electrically connected to a second signal source,
wherein the first signal line and the second signal line extend from a top surface of the organic insulating structure to two opposite side surfaces of the organic insulating structure respectively.

2. The display device according to claim 1, wherein the first signal source and the second signal source have different voltages.

3. The display device according to claim 1, wherein in a direction from the top surface of the organic insulating structure toward a bottom surface of the organic insulating structure, the first signal line does not overlap the second signal line.

4. The display device according to claim 1, wherein the organic insulating structure comprises stacked organic insulating layers, and individual widths of the organic insulating layers decrease from a bottom layer to a top layer among the organic insulating layers.

5. The display device according to claim 1, wherein the two opposite side surfaces of the organic insulating structure are linear, arc-shaped, or step-shaped.

6. The display device according to claim 1, wherein the first signal line and the second signal line are respectively electrically connected to conductive stacks disposed along the two opposite side surfaces of the organic insulating structure.

7. The display device according to claim 1, further comprising third signal lines, wherein the third signal lines are located in the organic insulating structure and are respectively electrically connected to signal sources.

8. The display device according to claim 7, wherein one of the third signal lines is electrically connected to the first signal line, and another one of the third signal lines is electrically connected to the second signal line.

9. The display device according to claim 8, wherein the one of the third signal lines is electrically connected to the first signal line through a first via, the another one of the third signal lines is electrically connected to the second signal line through a second via, and the first via and the second via are each independently located in the bridge region or the island region.

10. The display device according to claim 8, wherein the one and the another one of the third signal lines further extend along the two opposite side surfaces of the organic insulating structure respectively, and the one of the third signal lines is sandwiched between the first signal line and one of the two opposite side surfaces of the organic insulating structure, the another one of the third signal lines is sandwiched between the second signal line and the other of the two opposite side surfaces of the organic insulating structure.

11. A display device, having an island region and a bridge region adjacent to the island region, and comprising:
a pixel structure disposed in the island region;
an organic insulating structure located in the bridge region and comprising stacked organic insulating layers, wherein individual widths of organic insulating layers in the stacked organic insulating layers decrease from a bottom layer to a top layer among the organic insulating layers; and
a first signal line and a second signal line extending from the bridge region along the organic insulating structure to the island region, wherein the first signal line does not overlap the second signal line.

12. The display device according to claim 11, wherein the first signal line and the second signal line extend on a top surface and a side surface of the organic insulating structure.

13. The display device according to claim 11, wherein the pixel structure comprises a transistor and a light emitting device, the first signal line is electrically connected to the transistor, and the second signal line is electrically connected to the light emitting device.

14. The display device according to claim 11, further comprising a third signal line and a fourth signal line disposed within the organic insulating structure, wherein the third signal line is electrically connected to the first signal line, and the fourth signal line is electrically connected to the second signal line.

15. The display device according to claim 14, wherein the third signal line is electrically connected to a signal source Vdd, and the fourth signal line is electrically connected to a signal source Vss.

16. The display device according to claim 11, wherein in a cross-sectional view of the organic insulating structure, a top surface width of the organic insulating structure ranges from 13μm to 21μm, a height of the organic insulating structure ranges from 7.5μm to 18μm, and a bottom surface width of the organic insulating structure is a sum of the top surface width and 2/3 of the height.
